(19) United States
(12) Patent Application Publication
(10) Pub. No.: US 2007/0138550 A1
(43) Pub. Date: Jun. 21, 2007

(54) Semiconductor device and method for manufacturing semiconductor device

(75) Inventors: Hitoshi Ninomiya, Kanagawa (JP); Yoshinao Miura, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/637,919

(22) Filed: Dec. 13, 2006

(30) Foreign Application Priority Data
Dec. 20, 2005 (JP) 2005-366565

(51) Int. Cl. H01L 29/76

(52) U.S. Cl. 257/341

(57) ABSTRACT

Semiconductor device exhibiting higher breakdown voltage and method for manufacturing the same. A power MOSFET includes: a p-type first base region; a p-type second base region, formed in the first base region and containing a higher impurity concentration than the first base region; and an n-type source region, formed in first base region and joined to the first base region and the second base region, and placed in a position that is shallower than the second base region, a portion of the source region being provided on the second base region. The source region includes first source region that joins the first base region and a second source region that is continually provided in first source region and formed on the second base region. A joined surface of the second source region with the second base region is expanded to a side of the second source region.

This application is based on Japanese patent application No. 2005-366565, the content of which is incorporated hereinto by reference.

### BACKGROUND

1. Technical Field

The present invention relates to a semiconductor device and a method for manufacturing a semiconductor device.

2. Related Art

Heretofore, a type of semiconductor device such as Power Metal Oxide Semiconductor Field Effect Transistor (MOSFET), Insulated Gate Bipolar Transistor (IGBT) and the like is employed. A structure of a general vertical power MOSFET is shown in FIG. 9. This power MOSFET has an electric field relaxation region 902 having a conductivity type (n-type) on a semiconductor substrate 901 having a conductivity type (n-type). A base region 905 having an inverse conductivity type (p-type) is formed in the electric field relaxation region 902. Further, a source region 907 having conductivity type of n-type is provided in the base region 905. In addition, a P⁺ region 906 is provided for taking a backgating contact. A gate oxide film (gate insulating film) 903 is formed on a surface of the electric field relaxation region 902, and further a gate electrode 904 is formed on the gate oxide film 903. In addition, a source electrode 910 is provided on the surface of the source region 907, and a drain electrode 911 is provided on the back surface of the semiconductor substrate 901. In such MOS transistor (power MOSFET) 9, the semiconductor substrate 901 and the electric field relaxation region 902 serve as a drain, and a base region 905 right under the gate oxide film 903 serves as a channel. Here, an interlayer insulating film is indicated by 908 and a surface protective film is indicated by 909 in FIG. 9.

In the power MOSFET 9, when an electrical voltage that is higher than a breakdown voltage between the drain and the source are applied between the drain and the source as an inverse bias voltage, an avalanche break-down is generated. Since the avalanche break-down is, in general, generated at an edge of the base region, the avalanche current flows through a path indicated by an arrow shown in FIG. 9. Here, the power MOSFET 9 has an N-P-N structure composed of the electric field relaxation region 902, the base region 905 and the source region 907. When a flow of the avalanche current is occurred, an electrical voltage is generated due to a resistance of the base region 905, and when the electrical voltage is beyond a specified value, a parasitic bipolar transistor is switched on, leading to induce a flow of larger electric current locally, and eventually causing a failure of the device.

To provide a solution, a power MOSFET 8 as shown in FIG. 10 is proposed (for example, see Japanese Patent Laid-Open No. H5-243580). This type of power MOSFET 8 comprises a high concentration n-type region 81 serving as a drain layer and a low concentration n-type region 82 serving as a drain layer. A first base region 83 is formed in the low concentration n-type region 82, and a source region 84 and a second base region 85 containing higher impurity concentration than a first base region 83 are formed in this first base region 83.

To manufacture such power MOSFET 8, a gate oxide film 86 and a gate electrode 87 made of a polycrystalline silicon are formed on the low concentration n-type region 82, and then, an aperture is formed in the gate electrode 87. Thereafter, an impurity is injected through this aperture to form the first base region 83. Then, a second base region 85 containing higher impurity concentration than the first base region 83 is formed. Thereafter, a source region 84 is formed. Subsequently, an interlayer insulating film 88, a source electrode 89, a surface protective film 80 and a drain electrode D are provided. Since the second base region 85 having higher impurity concentration than the first base region 83 is formed more deeply than the source region 84 in such power MOSFET 8, it is considered that the impurity concentration of the base portion is higher so that h_{FE} is reduced, leading to improve an breakdown resistance.

However, in recent years, higher reliability is required for semiconductor devices, and thus an improvement in the breakdown voltage is required. It is difficult to meet such high level requirement by employing the configuration described in Japanese Patent Laid-Open No. H5-243,580.

### SUMMARY OF THE INVENTION

According to the present invention, there is provided a semiconductor device, comprising: a first base region having an inverse conductivity type, which is formed in a layer having a first conductivity type provided on a semiconductor substrate; a second base region having the inverse conductivity type, which is formed in said first base region and contains higher impurity concentration than said first base region; and a source region having the first conductivity type, which is formed in said first base region so as to be adjacent to said second base region, and a portion of said source region being provided on said second base region, being joined to said first base region and said second base region, and put in a position that is shallower than said second base region, wherein said source region includes: a first source region joined to said first base region; and a second source region continuously provided in said first source region and formed on said second base region, and wherein a joined surface of said second source region with said second base region is expanded to a side of said second source region.

In the technology described in Japanese Patent Laid-Open No. H5-243580, when the source region 84 is comparted into the second source region 84A joined to the second base region 85 and the first source region 84B joined to the first base region 83, it is evidenced as shown in FIG. 10 that a joined surface between the second base region 85 and the second source region 84A protrudes toward a side of the second base region 85. On the other hand, in the present invention, a joined surface of the second source region with the second base region is expanded toward a side of the second source region. Width of a portion of the second base region right under the joined surface of the second base region with the second source region is increased by an extent that the joined surface of the second source region with the second base region expands toward the side of the second source region, as compared with technology described in Japanese Patent Laid-Open No. H5-243580, and therefore a reduced resistance of the second base region can be assured.

Having such configuration, a semiconductor device having exhibiting higher breakdown voltage can be provided.

According to the present invention, there is provided a method for manufacturing a semiconductor device, comprising: a method for manufacturing a semiconductor device, comprising: forming a first base region having an inverse conductivity type in a layer having a first conductivity type provided on a semiconductor substrate; forming a region having the first conductivity type in said first base region; and forming a second base region having an inverse conductivity type, which is overlapped with a portion of said region having first conductivity type in said first base region, put in position that is deeper than said region having the first conductivity type, and contains higher impurity concentration than said first base region; wherein said forming the second base region includes providing a source region that is a portion of not overlapping with said second base region in said region having the first conductivity type by injecting an impurity of inverse conductivity type into said first base region and diffusing said impurity therein to form said second base region overlapping with a portion of said region having the first conductivity type.

According to the present invention, a semiconductor device having higher breakdown voltage and a method for manufacturing such semiconductor device can be provided.

### BRIEF DESCRIPTION OF THE DRAWINGS

The above and other objects, advantages and features of the present invention will be more apparent from the following description taken in conjunction with the accompanying drawings, in which:

FIG. 1 is a cross-sectional view, illustrating a power MOSFET according to first embodiment of the present invention;

FIG. 2 is a cross-sectional view, illustrating a process for manufacturing the power MOSFET;

FIG. 3 is a cross-sectional view, illustrating a process for manufacturing the power MOSFET;

FIG. 4 is a cross-sectional view, illustrating a process for manufacturing the power MOSFET;

FIG. 5 is a cross-sectional view, illustrating a process for manufacturing the power MOSFET;

FIG. 6 is a cross-sectional view, illustrating a process for manufacturing the power MOSFET;

FIG. 7 is a cross-sectional view, schematically showing a concentration distribution in the second base region of the power MOSFET;

FIG. 8 is a cross-sectional view, illustrating a power MOSFET according to second embodiment of the present invention;

FIG. 9 is a cross-sectional view, illustrating a conventional power MOSFET; and

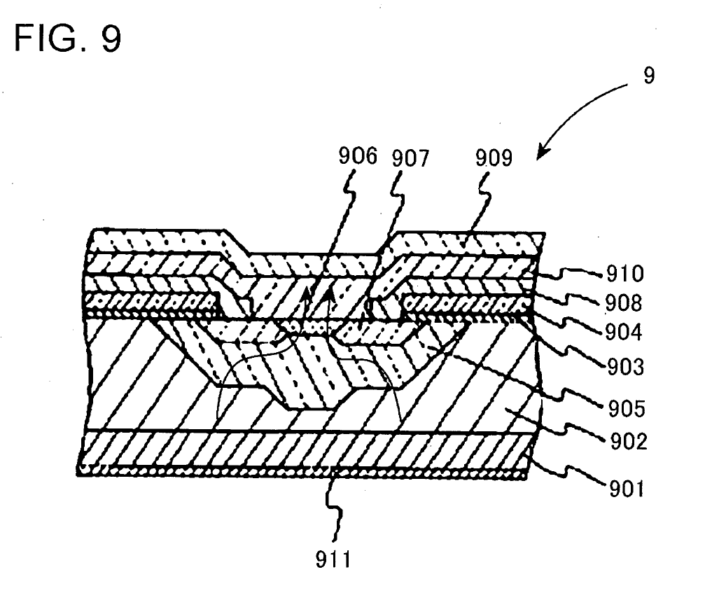

FIG. 10 is a cross-sectional view, illustrating a conventional power MOSFET.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments according to the present invention will be described as follows, in reference to the drawings. In all drawings, an identical numeral is assigned to an element commonly appeared in the drawings and redundant descriptions thereof will not be repeated.

### First Embodiment

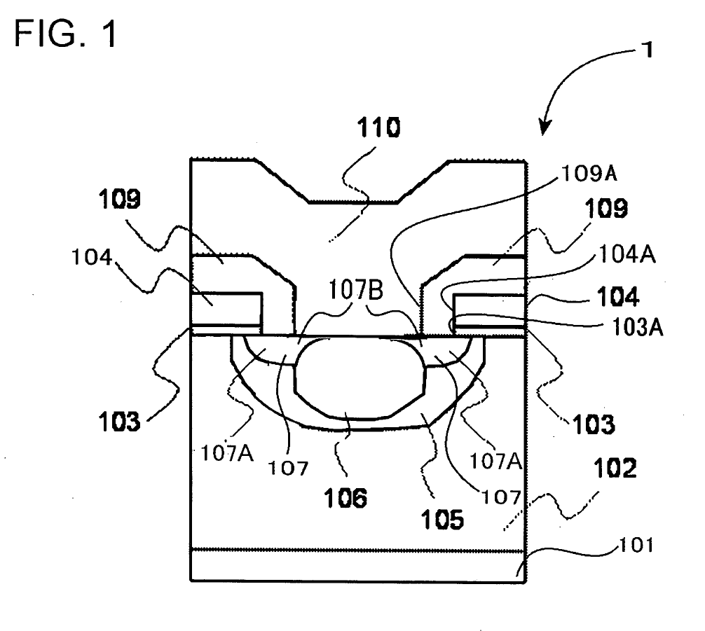

A cross-sectional view of a semiconductor device (power MOSFET) 1 according to the present embodiment is shown in FIG. 1. The cross-sectional view of FIG. 1 is a cross-sectional view along a direction perpendicular to surfaces of a silicon (Si) substrate 101 of the power MOSFET 1 and an electric field relaxation region 102 (i.e., perpendicular to a direction of stacking layers of the electric field relaxation region 102). First of all, an outline of the power MOSFET 1 will be described. The power MOSFET 1 includes:

a first base region 105 having an inverse conductivity type formed in an n-type electric field relaxation region 102 (a layer having a first conductivity type), which is provided on a semiconductor substrate (Si substrate) having the first conductivity type (n-type);

a second base region 106 having the inverse conductivity type, which is formed in the first base region 105 and contains higher impurity concentration than the first base region 105; and

a source region 107 having the first conductivity type (n-type), which is formed in first base region 105 and is joined to the first base region 105 and the second base region 106, and is put in position that is shallower than the second base region 106, a portion of the source region 107 being provided on the second base region 106.

The source region 107 includes first source region 107A that joins the first base region 105 and a second source region 107B that is continually provided in first source region 107A and formed on the second base region 106. In at least one cross section along a direction that is perpendicular to a direction of stacking layers of the electric field relaxation region 102, a joined surface of the second source region 107B with the second base region 106 is expanded to a side of the second source region 107B.

Details of the power MOSFET 1 will be described as follows.

The power MOSFET 1 includes the n-type Si substrate 101 serving as a semiconductor substrate and the n-type electric field relaxation region 102 formed on the Si substrate 101. The first base region 105 described above is formed in the electric field relaxation region 102, and the source region 107 and the second base region 106 are formed in such first base region 105.

The source region 107 is formed in the surface layer of the electric field relaxation region 102 to form a ring-shape, though it is not shown here. The source region 107 is formed so that the second source region 107B would be located on the inside of the first source region 107A. Depth of the second source region 107B from a surface of the electric field relaxation region 102 is shallower than depth of a bottom surface of the first source region 107A from the surface of the electric field relaxation region 102.

The second base region 106 is formed to be adjacent to the source region 107 so as to be sandwiched by the source region 107, viewed in the cross-sectional view of FIG. 1. A joined surface between the second source region 107B and the second base region 106 is curved toward the side of the second source region 107B, and is expanded toward the side of the second source region 107B.

In other words, the second base region 106 is formed so as to wedge in the second source region 107B, and is expanded toward the side of the surface of the electric field relaxation region 102.

The second base region 106 is formed in the surface layer of the electric field relaxation region 102 and further, is formed over the position that is deeper than such surface layer. The second base region 106 is formed to be deeper than the source region 107, and a peak position of the impurity concentration distribution in the second base region 106 is located at a deeper position (lower side of FIG. 1) than a peak position of the impurity concentration distribution in the source region 107. Here, an impurity concentration of the second base region 106 is higher than an impurity concentration of the source region 107. The impurity concentration of the second base region 106 is, for example, within a range of from 1×10¹⁹ cm⁻³ to 1×10²¹ cm⁻³. A cross-sectional geometry of the second base region 106 (cross-sectional geometry along a direction perpendicular to surfaces of Si substrate 101 and electric field relaxation region 102) is substantially oval-shaped. In addition, as shown in the cross-sectional view of FIG. 1, a width dimension (transverse dimension of FIG. 1) of the second base region 106 is smaller than a width dimension of the source region 107.

A gate insulating film 103 is formed on the surface of the electric field relaxation region 102. This gate insulating film 103 is in contact with the electric field relaxation region 102, the first base region 105, and the first source region 107A. A gate electrode 104 is formed on the gate insulating film 103. Apertures 103A and 104A are formed in the gate insulating film 103 and the gate electrode 104, respectively, and an interlayer insulating film (insulating film) 109 is provided so as to cover the circumferences of the gate electrode 104 and the apertures 103A and 104A. An aperture 109A is also formed in the interlayer insulating film 109, the second source region 107B of the source region 107 and the second base region 106 between the second source regions 107B are exposed through the aperture 109A. A source electrode 110 is provided on the interlayer insulating film 109, and the interlayer insulating film 109 isolates between the source electrode 110 and the gate electrode 104. The source electrode 110 is in contact with the second source region 107B and the second base region 106 via the aperture 109A formed in the interlayer insulating film 109.

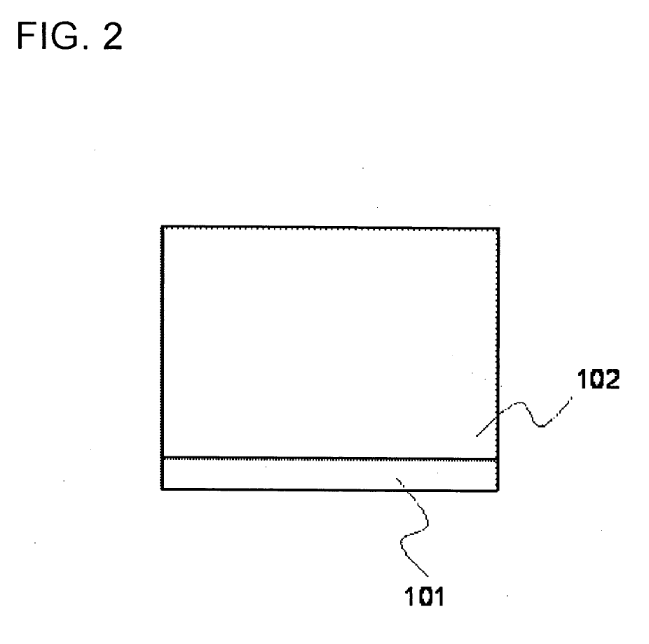

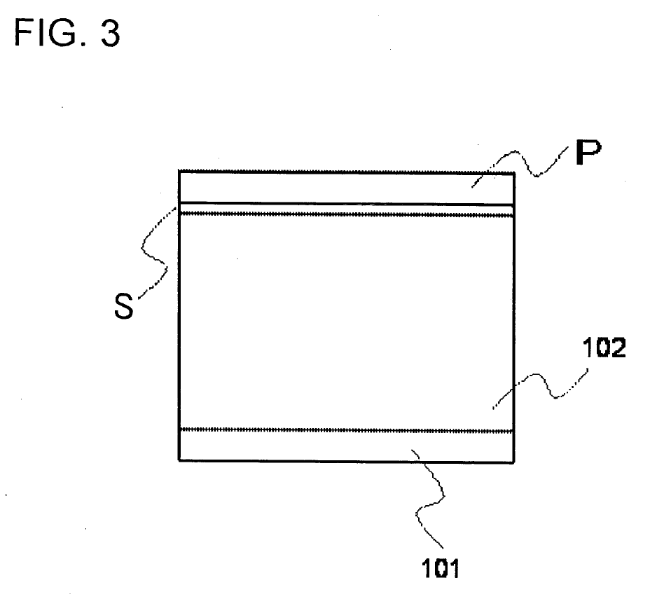

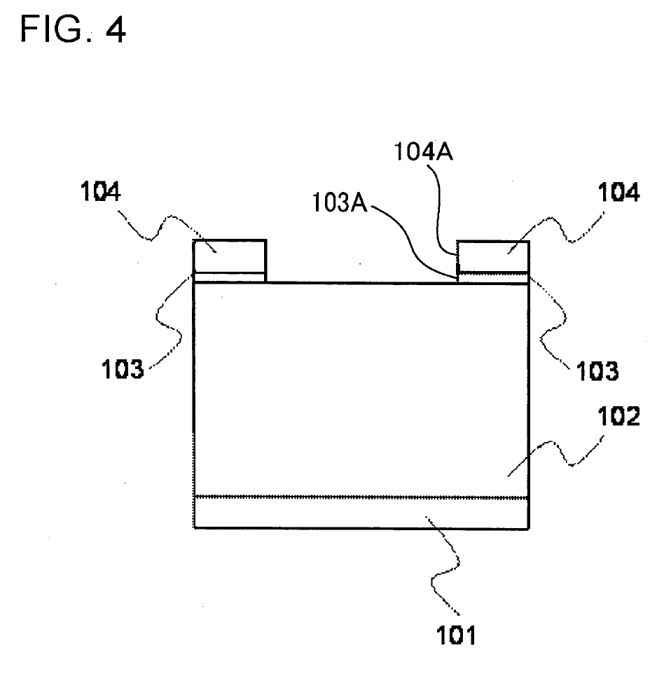

A manufacture of such power MOSFET 1 is carried out along the following process. Descriptions will be made in reference to FIG. 2 to FIG. 7. As shown in FIG. 2, a silicon (Si) substrate 101 doped with an n-type impurity at a concentration of about 1×10¹⁹ cm⁻³ is prepared, and an epitaxial growth process is conducted to form an electric field relaxation region 102 on the Si substrate 101. The electric field relaxation region 102 is an n-type Si layer, and an impurity concentration thereof is almost within a range of from 1×10¹⁵ to 1×10¹⁶ cm⁻³. Then, the surface of the electric field relaxation region 102 is oxidized at 900 degree C. under an atmosphere of a mixed gas of hydrogen (H₂) gas and oxygen (O₂) gas to form a silicon oxide film S having a thickness of about 500 angstroms on the surface of the electric field relaxation region 102. The silicon oxide film S will serve as a gate insulating film 103. Thereafter, a polysilicon film P is deposited on the surface of the silicon oxide film S to a thickness of about 4,000 angstroms by a reduced pressure CVD process, and then, phosphorus is thermally diffused under a phosphorous tri-chloride (PCl₃) atmosphere at 920 degree C., thereby changing the conductivity type of the polysilicon film P into n-type (see FIG. 3). Then, by employing a photolithographic technology, the polysilicon film P and the silicon oxide film S are selectively etched by a reactive ion etching (RIE) to form apertures 103A and 104A in the polysilicon film P and the silicon oxide film S. Such procedure gives the gate insulating film 103 and the gate electrode 104 formed the apertures 103A and 104A (see FIG. 4).

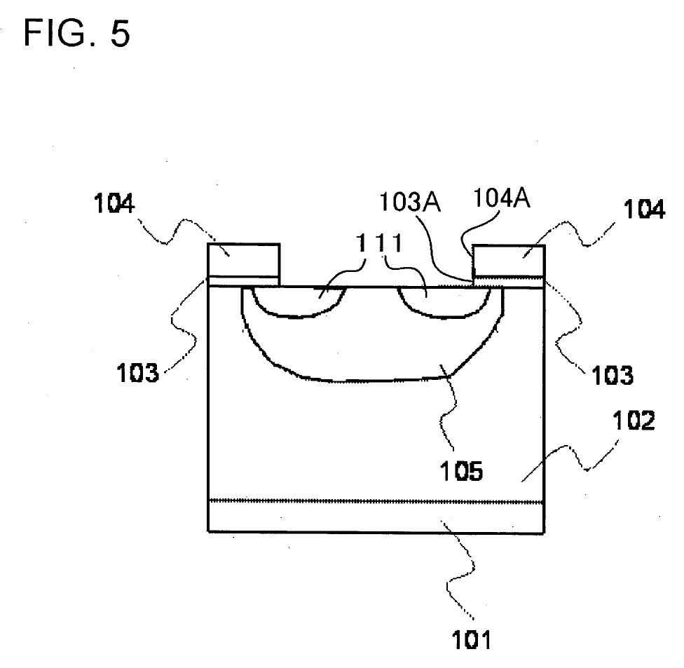

Thereafter, boron is ion-implanted via apertures 103A and 104A through a mask of the gate electrode 104 at an accelerating voltage of 70 keV and a dose level of 2.0×10¹³ cm⁻², and then, a thermal processing is performed under a nitrogen gas (N₂) atmosphere at 1,100 degree C. for 60 minutes to form a p-type first base region 105. Then, a photo resist (not shown) is formed on the exposed surface of the electric field relaxation region 102 (in this case, surface of first base region 105) through the apertures 103A and 104A by employing a photolithographic technology. Arsenic is ion-implanted via the apertures 103A and 104A through a mask of the photo resist and the gate electrode 104 at an accelerating voltage of 50 keV and a dose level of 2.0×10¹⁵ cm⁻², and then, a thermal processing is performed under an N₂ atmosphere at 850 degree C. for 30 minutes. Having such procedure a region 111 having single conductivity type serving as the n-type source region 107 is formed (see FIG. 5).

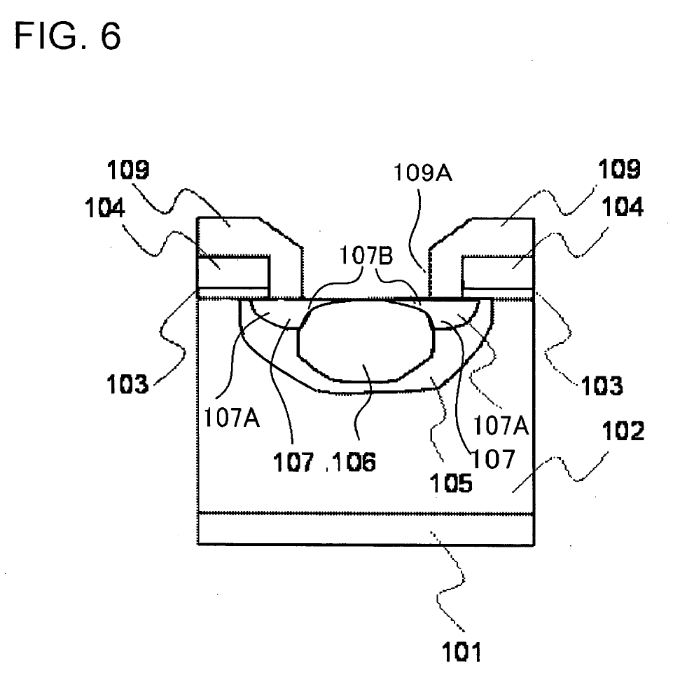

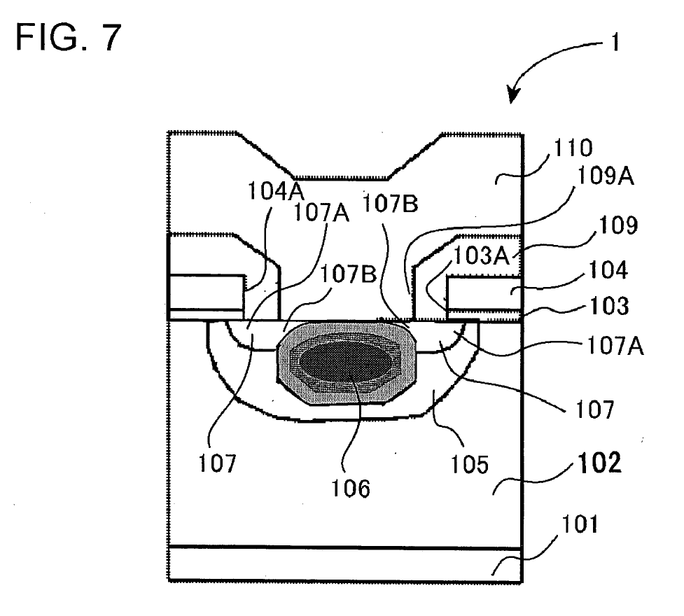

Thereafter, a borophospho silicate glass (BPSG) serving as the interlayer insulating film 109 is deposited on the surfaces of the gate electrode 104 and the electric field relaxation region 102 to a thickness of about 8,000 angstroms by a normal pressure CVD process. Thereafter, the BPSG is selectively etched by employing a photolithographic technology to provide the interlayer insulating film 109 formed the aperture (contact hole) 109A. Then, boron difluoride (BF₂) is ion-implanted via the aperture 109A through a mask of the interlayer insulating film 109 at a dose level within a range of from 1×10¹⁴ cm⁻² to 2×10¹⁶ cm⁻², preferably at a dose level of 5.0×10¹⁵ cm⁻² and an accelerating voltage of 70 keV. Thereafter, a thermal processing is performed under an N₂ atmosphere at a temperature of 850 degree C. for 30 minutes to diffuse impurity, thereby forming the second base region 106 (see FIG. 6). Here, the diffusion of impurity made an overlapping of a portion of the region 111 having a single conductivity type with the second base region 106. Having such procedure, the second source region 107B of the source region 107 is formed, and formation processes for the second base region 106 and the source region 107 are substantially simultaneously carried out. More specifically, other portions of the region 111 having a single conductivity type (portions without overlapping with the second base region 106) serves as the source region 107. In addition to above, a distribution of an impurity concentration in the second base region 106 shows a profile, in which impurity concentration gradually decreases from a center toward outside, as shown in FIG. 7 (in FIG. 7, deep colored portion indicates a portion of higher concentration, and light colored portion indicates a portion of lower concentration).

Thereafter, an aluminum alloy is sputtered and deposited so as to fill on the interlayer insulating film 109 and to fill the aperture 109A of the interlayer insulating film 109. Next, by employing a photolithographic technology, the aluminum alloy is selectively removed by etching to form the source electrode 110.

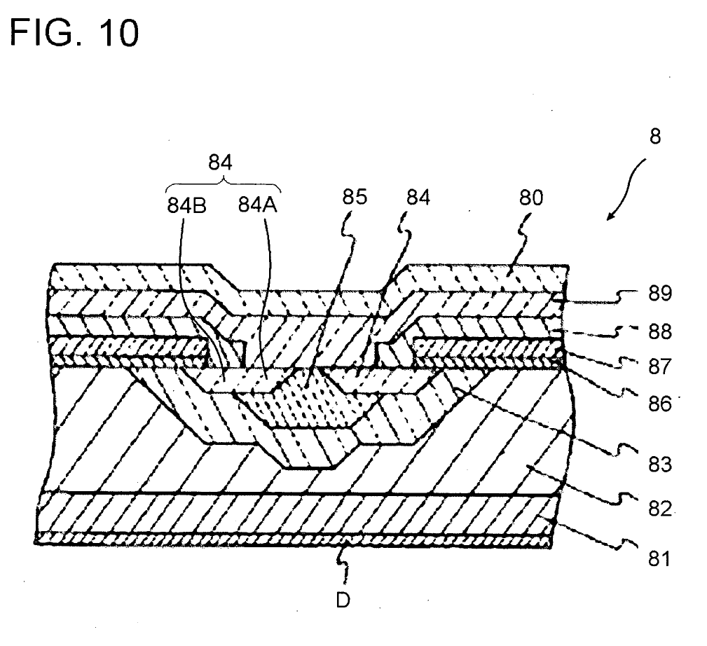

Advantageous effects obtainable by employing the configuration of the above-described power MOSFET 1 will be described as follows. In the power MOSFET 1 of the present embodiment, the joined surface between the second base region 106 and the second source region 107B is expanded toward the side of the second source region 107B (side of surface of electric field relaxation region 102). By contrast, in the technology described in Japanese Patent Laid-Open No. H5-243580 as shown in FIG. 10, a joined surface between the second base region 85 and the second source region 84A protrudes toward a side of the second base region 85 (back surface of electric field relaxation region 102). A width of the portion of the second base region 106 right under the joined surface between the second base region 106 and the second source region 107B is increased by an extent of the joined surface with second base region 106 of second source region 107B expanding toward the side of the second source region 107B, as compared with the technology described in Japanese Patent Laid-Open No. H5-243580 as shown in FIG. 10, so that a reduced resistance of the second base region 106 can be assured. Having this configuration, the power MOSFET 1 exhibiting higher breakdown voltage can be provided. In addition to above, the power MOSFET 1 having such structure can be obtained only by a procedure, which includes forming the region 111 having a single conductivity type serving as the source region 107, and then injecting an impurity of inverse conductivity to form the second base region 106.

Further, since the present embodiment employs the impurity concentration in the second base region 106 of within a range of from 1×10¹⁹ cm⁻³ to 1×10²¹ cm⁻³, a resistance of the second base region 106 can be reduced, such that this configuration can provide the power MOSFET 1 exhibiting higher breakdown voltage.

In addition, a drain-source breakdown voltage of the power MOSFET 1 is determined by a junction of the electric field relaxation region 102 with the first base region 105. Here, an impurity concentration of the first base region 105 is lower than an impurity concentration of the second base region 106. Therefore, the second base region 106 is formed to expand out of the first base region 105, and therefore the power MOSFET 1 of the present embodiment can ensure higher drain-source breakdown voltage, as compared with a structure that provides a drain-source breakdown voltage determined by the junction of the second base region 106 and the electric field relaxation region 102.

Further, in the present embodiment, the first base region 105 is formed via self-align through a mask of the gate electrode 104, and the second base region 106 is formed via self-align through a mask of the interlayer insulating film 109. As such, since a lithographic operation employing a photo mask is not required for forming the first base region 105 and the second base region 106, the process for manufacturing the power MOSFET 1 can be simplified.

### Second Embodiment

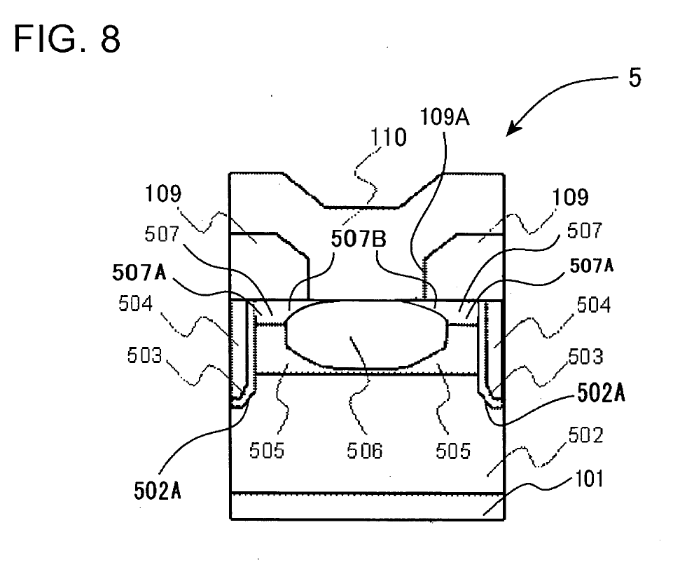

Next, second embodiment of the present invention will be described in reference to FIG. 8. The power MOSFET 1 of the aforementioned embodiment includes the gate insulating film 103 and the gate electrode 104 provided on the electric field relaxation region 102. On the contrary, in a power MOSFET 5 of the present embodiment, a gate insulating film 503 and a gate electrode 504 are embedded within the electric field relaxation region 502. More specifically, the power MOSFET 5 of the present embodiment includes, similarly as in the aforementioned embodiment, an n-type of Si substrate 101 and an n-type of electric field relaxation region (layer having a single conductivity type) 502. A trench 502A is formed in the electric field relaxation region 502 This trench 502A is formed to be lattice-shaped in plan view, though it is not shown. A gate insulating film 503 is deposited on a side wall and a bottom surface of the trench 502A, and further, a gate electrode 504 is formed on this gate insulating film 503.

A p-type first base region 505 is formed in a region, which is enclosed by the trench 502A and is comparted by the trench 502A, and a p-type second base region 506 is formed in the first base region 505. An impurity concentration of the second base region 506 is similar to that of the aforementioned embodiment, and is higher than that of the first base region 505. In addition, an impurity concentration of the second base region 506 is higher than an impurity concentration of the source region 507 as will be discussed later, similarly as in the aforementioned embodiment. The second base region 506 is formed in the surface layer of the electric field relaxation region 502 and further, is formed over the position that is deeper than such surface layer. The second base region 506 is formed to be deeper than the n-type source region 507 as will be discussed later, and a peak position of the impurity concentration distribution in the second base region 506 is located at a deeper position (lower side of FIG. 8) than a peak position of the impurity concentration distribution in the source region 507. A cross-sectional geometry of the second base region 506 (cross-sectional geometry along a direction perpendicular to surfaces of Si substrate 101 and electric field relaxation region 502) is substantially oval-shaped. In addition, as shown in the cross-sectional view of FIG. 8, a width dimension (transverse dimension of FIG. 8) of the second base region 506 is smaller than a width dimension of the source region 507 as will be discussed later Further, the source region 507 adjacent to the second base region 506 is formed in the first base region 505. The source region 507 is formed in the surface layer of the electric field relaxation region 502 to form a ring-shape. The source region 507 includes: a second source region 507B, which is formed on the second base region 506, is joined with the second base region 506 and is in contact with source electrode 110; and a first source region 507A, which is provided continuously with the second source region 507B and is joined with the first base region 505. A joined surface of the second source region 507B with the second base region 506 is curved and expanded toward the side of the second source region 107B. In other words, the second base region 506 is formed so as to wedge in the second source region 507B, and is curved and expanded toward the side of the surface of the electric field relaxation region 502.

Further, the second source region 507B is located on the inside of the first source region 507A, and the first source region 507A is adjacent to the trench 502A. The first source region 507A is insulated from the gate electrode 504 by the gate insulating film 503. Here, depth of the second source region 507B from a surface of the electric field relaxation region 502 is shallower than depth of a bottom surface of the first source region 507A from the surface of the electric field relaxation region 502.

In addition, the interlayer insulating film 109 having a similar configuration as employed in the aforementioned embodiment is provided on surface of the electric field relaxation region 502. An aperture 109A is formed in the interlayer insulating film 109, and the second source region 507B of the source region 507 and the second base region 506 are exposed through the aperture 109A. Further, a source electrode 110 is provided on the interlayer insulating film 109. The source electrode 110 covers the interlayer insulating film 109 and the aperture 109A of the interlayer insulating film 109, and is in contact with the second source region 507B and the second base region 506.

Next, a process for manufacturing the power MOSFET 5 having such structure will be described as follows. Similarly as in the aforementioned embodiment, a silicon (Si) substrate 101 is prepared, and an epitaxial growth process is conducted to form an electric field relaxation region 502 on the Si substrate 101. The electric field relaxation region 502 is composed of an n-type Si layer, similarly as the electric field relaxation region 102, and an impurity concentration thereof is similar to that of the electric field relaxation region 102. Then, by employing a photolithographic technology, the electric field relaxation region 502 is selectively and anisotropically etched by RIE to form a trench 502A having a depth of depth of about 1.0 μm and a width of about 0.5 μm.

Thereafter, the surface of the electric field relaxation region 502 and a surface of the trench 502A (side wall and bottom surface) is oxidized at 900 degree C. under an atmosphere of a mixed gas of H₂ gas and O₂ gas to form a silicon oxide film S having a thickness of about 500 angstroms. Next, a polysilicon film is deposited on the aforementioned silicon oxide film to a thickness of about 10,000 angstroms via a reduced pressure CVD process. In addition to above, an interior of the trench 502A is filled with a polysilicon film. Then, phosphorus is thermally diffused under a phosphorous trichloride (PCl₃) atmosphere at 920 degree C., thereby changing the conductivity type of the polysilicon film into n-type. The polysilicon film is etched by RIE, and portions of the polysilicon film and the silicon oxide film disposed in locations other than the interior of the trench 502A are selectively removed, while portions of the polysilicon film and the silicon oxide film disposed in the interior of the trench 502A are remained by suitably adjusting the etching time. The portion of the silicon oxide film remained in the interior of the trench 502A serves as the gate insulating film 503, and the portion of the polysilicon film remained in the interior of the trench 502A serves as the gate electrode 504.

Next, a p-type first base region 505 is formed in a region comparted by the trench 502A. Process conditions for forming the first base region 505 is the same as the process conditions for forming the first base region 105 of the aforementioned embodiment. Thereafter, a photo resist (not shown) is formed on a predetermined region of the surface of the electric field relaxation region 502 by employing a photolithographic technology. Then, a region having a single conductivity type, which serves as the source region 507 is formed through a mask of photo resist. Process conditions for forming the region having a single conductivity type and other conditions are the same as the process conditions employed in the aforementioned embodiment. Next, the interlayer insulating film 109 is provided by a process same as employed in the aforementioned embodiment, and further, the aperture 109A is formed in the interlayer insulating film 109. An impurity is injected thereto through the aperture 109A of the interlayer insulating film 109 to form the second base region 506. Process conditions for forming the second base region 506 is the same as the process conditions for forming the second base region 106 of the aforementioned embodiment. By forming the second base region 506, the second base region 506 overlaps with a portion of the region having a single conductivity type, thereby forming the second source region 507B of the source region 507. More specifically, similarly as in the aforementioned embodiment, the formation processes for the second base region 506 and the source region 507 are substantially simultaneously carried out.

According to the present embodiment, the following advantageous effects can be provided, in addition to the similar advantageous effects as obtained in the aforementioned embodiment. Since the region for forming the first base region 505 is comparted by the trench 502A, which has the gate insulating film 503 and the gate electrode 504 provided in the interior thereof, it is not necessary to provide a mask on the surface of the electric field relaxation region 502, when the first base region 505 is formed. Having this configuration, the process for manufacturing the power MOSFET 5 can be simplified.

It is not intended that the present invention is limited to the configurations illustrated in the above-described embodiment, and various modifications or improvements thereof are within the scope of the present invention, provided that these can also achieve the object of the present invention. While the n-type Si substrate 101 has been employed for the semiconductor substrate in the aforementioned embodiment, the available substrate is not limited thereto, and a p-type semiconductor substrate may alternatively be employed. More specifically, the present invention can be applied to IGBT, in addition to the power MOSFET.

Further, while the impurity concentration of the second base region 106 is within a range of from 1×10¹⁹ cm⁻³ to 1×10²¹ cm⁻³ in the aforementioned embodiment, the available impurity concentration is not limited thereto.

It is apparent that the present invention is not limited to the above embodiment, and may be modified and changed without departing from the scope and spirit of the invention.

What is claimed is:

1. A semiconductor device, comprising:
a first base region having an inverse conductivity type, which is formed in a layer having a first conductivity type provided on a semiconductor substrate;
a second base region having the inverse conductivity type, which is formed in said first base region and contains higher impurity concentration than said first base region; and
a source region having the first conductivity type, which is formed in said first base region so as to be adjacent to said second base region, and a portion of said source region being provided on said second base region, being joined to said first base region and said second base region, and put in a position that is shallower than said second base region,
wherein said source region includes:
a first source region joined to said first base region; and
a second source region continuously provided in said first source region and formed on said second base region, and
wherein a joined surface of said second source region with said second base region is expanded to a side of said second source region.

2. The semiconductor device according to claim 1, wherein portions of said second source region and said second base region are formed in a surface portion and in contact with a source electrode provided on said second 5 source region and said second base region.

3. The semiconductor device according to claim 1, wherein a trench for comparting said first base region is formed in said layer having the first conductivity type, and a gate electrode is formed in said trench.

4. The semiconductor device according to claim 1, wherein an impurity concentration of said first and second source regions is lower than an impurity concentration of said second base region.

5. The semiconductor device according to claim 1, wherein an impurity concentration of said second base region is within a range of from 1×10¹⁹ cm⁻³ to 1×10²¹ cm⁻³.

6. A method for manufacturing a semiconductor device, comprising:
forming a first base region having an inverse conductivity type in a layer having a first conductivity type provided on a semiconductor substrate;
forming a region having the first conductivity type in said first base region; and
forming a second base region having an inverse conductivity type, which is overlapped with a portion of said region having first conductivity type in said first base region, put in position that is deeper than said region having the first conductivity type, and contains higher impurity concentration than said first base region;
wherein a source region is formed in a portion of said region having the first conductivity type except an area formed said second base region.

7. The method for manufacturing a semiconductor device according to claim 6,
wherein said forming the first base region includes forming the first base region by forming a gate electrode having an aperture on said layer having the first conductivity type, and thereafter injecting an impurity of inverse conductivity type from the aperture of said gate electrode, after said gate electrode having the aperture is formed on said layer having the first conductivity type,
wherein said forming the region having the first conductivity type includes forming said region having the first conductivity type by injecting an impurity having the first conductivity type from the aperture of said gate electrode, and
wherein said forming the second base region includes forming an insulating film on said gate electrode, which has a smaller aperture than the aperture of said gate electrode and injecting an impurity of inverse conductivity type into said first base region through an aperture of said insulating film.

8. The method for manufacturing a semiconductor device according to claim 6,
wherein said forming the first base region includes forming a trench for comparting the first base region in said layer having the first conductivity type, forming a gate electrode in the trench, and thereafter, injecting an impurity of inverse conductivity type into the region comparted by said trench to form the first base region,
wherein said forming the region having the first conductivity type includes forming the region having the first conductivity type by injecting an impurity having the first conductivity type in said first base region formed in the region comparted by said trench, and
wherein said forming the second base region includes forming an insulating film having an aperture on said layer having the first conductivity type and injecting an impurity of inverse conductivity type into said first base region through the aperture of said insulating film.
